(19) United States
(12) Patent Application Publication
(10) Pub. No.: US 2026/0094630 A1
(43) Pub. Date: Apr. 2, 2026

(54) PROCESSING METHOD, ELECTRONIC DEVICE, AND STORAGE MEDIUM

(71) Applicant: Smarter Silicon (Shanghai) Technologies Co., Ltd., Shanghai (CN)

(72) Inventors: Xihua FAN, Shanghai (CN); Yi WANG, Shanghai (CN); Wei WANG, Shanghai (CN)

(21) Appl. No.: 19/337,394

(22) Filed: Sep. 23, 2025

(30) Foreign Application Priority Data
Sep. 30, 2024 (CN) 202411395868.6

(51) Int. Cl. G11C 7/10

(52) U.S. Cl. CPC G11C 7/1006

(57) ABSTRACT

A processing method, an electronic device, and a storage medium are provided in the present disclosure. The processing method includes in response to that an access operation of a first row in a storage space of a storage component is detected, obtaining a row address of the first row; and in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set. Original row information recorded in a first primary recording unit satisfies a first access condition; and each recording unit is configured to record row information of a corresponding storage row in the storage space.

### CROSS-REFERENCE TO RELATED APPLICATION

This application claims the priority of Chinese Patent Application No. 202411395868.6, filed on Sep. 30, 2024, the content of which is incorporated herein by reference in its entirety.

### TECHNICAL FIELD

The present disclosure generally relates to the field of computer technology, and, more particularly, relates to a processing method, an electronic device, and a storage medium.

### BACKGROUND

Refresh management (RFM) of storage components such as DDR (double data rate) memory chips and the like may ensure data integrity. Frequent access to same row of the storage component such as the DDR memory chip or the like may cause bit flip phenomenon in adjacent rows, known as row hammer (RH). To ensure the accuracy of data in adjacent rows, additional refreshes may be needed for adjacent rows. However, existing techniques may suffer from the problem that the row addresses refreshed by RFM may not be optimal, which may be difficult to satisfy refresh needs for adjacent rows of frequently accessed rows.

### SUMMARY

One aspect of the present disclosure provides a processing method. The processing method includes in response to that an access operation of a first row in a storage space of a storage component is detected, obtaining a row address of the first row; and in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set. Original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

Another aspect of the present disclosure provides an electronic device. The electronic device includes a memory, configured to store a computer program; and one or more processors, configured to, when the computer program is executed, perform a processing method. The processing method includes in response to that an access operation of a first row in a storage space of a storage component is detected, obtaining a row address of the first row; and in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set. Original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

Another aspect of the present disclosure provides a non-transitory computer-readable storage medium containing a computer program that, when being executed, causes one or more processors to perform a processing method. The processing method includes in response to that an access operation of a first row in a storage space of a storage component is detected, obtaining a row address of the first row; and in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set. Original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

Other aspects of the present disclosure may be understood by those skilled in the art in light of the description, the claims, and the drawings of the present disclosure.

### BRIEF DESCRIPTION OF THE DRAWINGS

To more clearly illustrate the technical solutions of embodiments of the present disclosure, accompanying drawings required in embodiments of the present disclosure are briefly described hereinafter. Obviously, accompanying drawings described below may be some embodiments of the present disclosure. Those skilled in the art may obtain other accompanying drawings based on above-mentioned accompanying drawings without creative work.

FIG. 1 illustrates a flow chart of a processing method according to various embodiments of the present disclosure.

FIG. 2 illustrates another flow chart of a processing method according to various embodiments of the present disclosure.

FIG. 3 illustrates exemplary information recording and replacement mechanism for primary/auxiliary recording units according to various embodiments of the present disclosure.

FIG. 4 illustrates exemplary row information recording and replacement when alternating accessing two storage rows in an LFU algorithm according to various embodiments of the present disclosure.

FIG. 5 illustrates exemplary row information recording and replacement when alternating accessing two storage rows according to various embodiments of the present disclosure.

FIG. 6 illustrates a compositional structural schematic of a processing device according to various embodiments of the present disclosure.

FIG. 7 illustrates a compositional structural schematic of an electronic device according to various embodiments of the present disclosure.

### DETAILED DESCRIPTION

To clearly describe the objectives, the technical solutions and advantages of the present disclosure, the technical solutions of the present disclosure are further described in detail below in combination with accompanying drawings and embodiments. The described embodiments should not be regarded as limiting the present disclosure. All other embodiments obtained by those skilled in the field without creative work are within the protection scope of the present disclosure.

Embodiments of the present disclosure provide a processing method and a processing device, which may be configured to solve the problem in existing technique that the row addresses refreshed by RFM may be not optimal to make difficult to accurately determine the rows which have refresh needs, thereby desirably satisfying refresh needs of adjacent rows of frequently accessed rows and avoiding bit flip in adjacent rows caused by frequent access to same row.

The processing method provided in embodiments of the present disclosure may be applied to electronic devices in a wide range of general-purpose or specialized computing environments or configurations, such as personal computers, server computers, handheld or portable devices, tablet devices, multi-processor devices, and the like.

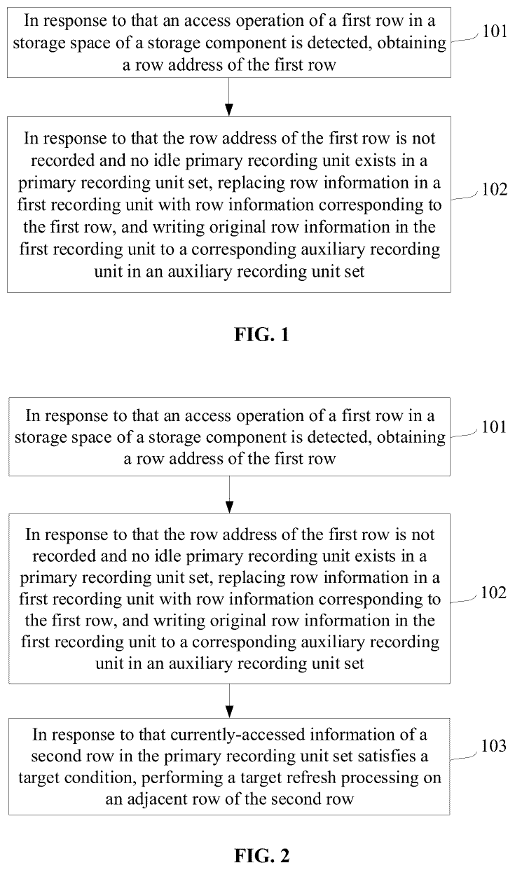

FIG. 1 illustrates a flow chart of a processing method according to various embodiments of the present disclosure. Referring to in FIG. 1, the processing method provided in embodiments of the present disclosure may include at least following exemplary steps 101 to 102, and such exemplary steps are described in detail hereinafter.

At 101, in response to that an access operation of a first row in a storage space of a storage component is detected, a row address of the first row may be obtained.

The storage component may be a chip with storage space in the electronic device for providing storage capability. For example, the storage component may be, but may be not limited to, a memory chip with storage capability or a chip used in non-memory storage scenario, such as DDR memory chip. In embodiments of the present disclosure, the storage component may be the memory chip, which may be taken as an example for solution description.

The storage space of the storage component may provide multiple storage rows for storing data and support data access operations, such as read/write operations or the like, on the data stored in each storage row.

The “row” mentioned in embodiments of the present disclosure may refer to the storage row provided by the storage space of the storage component.

The RFM refresh management of storage components such as DDR memory chips and memory chips may ensure data integrity. Frequent access to same row of the storage component, such as the DDR memory chip or the like, may cause bit flip phenomenon in adjacent rows, known as row hammer (RH). To ensure the accuracy of data in adjacent rows, additional refresh processing may be needed for adjacent rows.

To optimize the row addresses targeted by RFM refresh and accurately identify the rows needs to be refreshed (e.g., rows adjacent to frequently accessed rows), embodiments of the present disclosure provide a refresh processing solution based on the LFU (least frequently used page-replacement algorithm) optimization. That is, the processing method provided in embodiments of the present disclosure may be the refresh processing solution based on LFU optimization. Furthermore, optionally, such solution may be a DRFM (directed-RFM) refresh processing solution based on LFU optimization. DRFM, as supplementary refresh management commands, may be primarily configured to address the row hammer problem.

In solutions provided by embodiments of the present disclosure, the access operations of each storage row in the storage space of the storage component may first be detected. For example, access operations, including read or write data, of each storage row may be detected; and in response to that the access operation to the first row in the storage space of the storage component is detected, the row address of the first row may be obtained.

At 102, in response to that the row address of the first row is not recorded and no idle primary recording unit exists in a primary recording unit set, the row information (i.e., message, value and the like) in the first recording unit may be replaced with the row information corresponding to the first row, and original row information in the first recording unit may be written to corresponding auxiliary recording unit in an auxiliary recording unit set.

In embodiments of the present disclosure, the primary recording unit set and the auxiliary recording unit set may be preset for the storage component. The primary recording unit set may include a plurality of primary recording units, and the auxiliary recording unit set may include a plurality of auxiliary recording units. Each recording unit in the primary recording unit set and the auxiliary recording unit set may be configured to record row information of corresponding storage row in the storage space of the storage component. The row information may include a row address and currently-accessed information for the storage row indicated by the row address. Currently-accessed information may be configured to determine whether refresh operation is needed for adjacent rows of corresponding storage row.

Optionally, each recording unit may be configured to record row information of one storage row at a time.

Currently-accessed information stored in each primary recording unit may include, but may be not limited to, current corresponding count information (i.e., count value) of the number of accessed times of corresponding storage row and/or information such as access frequency, frequency level and the like. Similarly, currently-accessed information stored in each auxiliary recording unit may also include current corresponding count information of the number of accessed times of corresponding storage row and/or information such as access frequency, frequency level and the like. Furthermore, the row information recorded in each auxiliary recording unit of the auxiliary recording unit set may be the information of a few rows that have been replaced from the primary recording unit set.

In embodiments of the present disclosure, currently-accessed information of the storage row may be primarily current corresponding count information of the number of accessed times of the storage row.

In embodiments of the present disclosure, based on the primary recording unit set and the auxiliary recording unit set, row information such as the row address and currently-accessed information (e.g., current corresponding count information of the number of accessed times of the storage row) of the storage row in the storage component may be recorded, thereby obtaining the access status of each storage row in the storage component. In such way, the storage row which actually has refresh needs may be accurately determined based on the access status of each storage row in the storage component, thereby performing refresh processing on corresponding storage row.

It should be noted that the storage component may include a large quantity (number) of storage rows. For example, the memory chip may include a large quantity of storage rows; and exemplarily, a quantity of storage rows may be determined by the memory capacity and bit width. As disclosed above, in actual applications, considering resource overhead and usage constraints, total number of recording units included in the primary recording unit set and the auxiliary recording unit set may be less than, or significantly less than, the number of storage rows in the storage component.

To solve above-mentioned problems, embodiments of the present disclosure further provide a corresponding storage and replacement mechanism. Based on above-mentioned storage and replacement mechanism, row information of corresponding storage rows in the recording units provided by the primary recording unit set and the auxiliary recording unit set may be recorded and dynamically replaced as needed; and each recording unit provided by the primary recording unit set and the auxiliary recording unit set may be not configured to record row information of certain few storage rows, thereby accurately and efficiently obtaining the access status of each storage row in the storage component based on limited number of recording units, and precisely determining the storage row which actually has refresh needs and performing corresponding refresh processing accordingly.

In embodiments of the present disclosure, each primary recording unit provided by the primary recording unit set may be configured to store the row information for storage rows with high access frequency and/or short latest access time; and each auxiliary recording unit provided by the auxiliary recording unit set may be configured to store the row information for a number of storage rows that were recently replaced from the primary recording unit based on the LFU algorithm. Based on the above, after original row information in the primary recording unit is replaced, replaced original row information may be not immediately cleared, thereby supporting that when the row characterized by original row information is accessed in subsequent period, accessed information of such storage row may be updated based on original row information. Furthermore, it may be convenient for accurately obtaining accessed information of such storage row and accurately determining the storage row which actually has refresh needs and performing corresponding refresh processing accordingly. The storage and replacement mechanism of the primary recording unit set and the auxiliary recording unit set are explained in detail subsequently.

It should be noted that the latest access time corresponding to a row may refer to the time when the storage row was last accessed. Short latest access time of a row may refer to a short interval between the latest access time of such row and current time.

Based on the storage and replacement mechanism, based on obtaining the row address of the first row in response to that the access operation to the first row in the storage space of the storage component is detected, it may further determine whether the row address of the first row is currently recorded and the recording status of each primary recording unit in the primary recording unit set is determined. The recording status of each primary recording unit in the primary recording unit set may be either idle or non-idle, which may depend on actual application.

In one embodiment, in response to that the row address of the first row is not recorded and no idle primary recording unit exists in the primary recording unit set, the row information in the first recording unit may be replaced with the row information corresponding to the first row, and original row information in the first recording unit may be written to corresponding auxiliary recording unit in the auxiliary recording unit set.

The original row information recorded in the first primary recording unit may satisfy the first access condition. The row information in corresponding primary recording unit satisfying the first access condition may characterize that replacement of the row information in corresponding primary recording unit is allowed.

For the scenario that the row address of the first row is not currently recorded and no idle primary recording unit exists in the primary recording unit set, exemplarily, the first recording unit satisfying the first access condition may be first determined from the primary recording unit set; the original row information in the first recording unit may be then written to corresponding auxiliary recording unit in the auxiliary recording unit set to free the first recording unit; and the row information of the first row (e.g., the row address and currently-accessed information of the first row) may then be written to the first recording unit.

Currently-accessed information of the first row may include current count information (i.e., value) corresponding to a quantity (number) of accessed times of the first row, which may be taken as an example for description. Since no historical storage information of the first row is currently in the primary recording unit set, no historical count information may exist correspondingly. Therefore, current count information corresponding to the number of accessed times of the first row may be generated directly based on the access operation to the first row currently detected. Assuming the count starts at 0 and increments by 1 with each access, current count value (i.e., information, message or the like) corresponding to the number of accessed times of the first row may be 1. Accordingly, the row address of the first row and current count value “1” of the number of accessed times of the first row may be stored in the first recording unit.

Optionally, the first access condition may include that the count value of corresponding storage row is a count value satisfying the first numerical condition in multiple count values recorded in the primary recording unit set; and in response to that multiple count values satisfy the first numerical condition, the count value of corresponding storage row is a count value satisfying the first time condition in multiple count values satisfying the first numerical condition.

Based on the first access condition, whether the count value of the storage row satisfies the first numerical condition in multiple count values recorded in the primary recording unit set may be first determined. When the count value of the storage row satisfies the first numerical condition in multiple count values recorded in the primary recording unit set, and when multiple count values in the recording unit set satisfy the first numerical condition, whether the count value of the storage row satisfies the first time condition may continue to be determined. In response to that the first time condition is satisfied, the count value of the storage row may be determined to satisfy the first access condition. In response to that the first time condition is not satisfied, the count value of the storage row may be determined to not satisfy the first access condition.

For the scenario that the count value of the storage row satisfies the first numerical condition in all count values recorded in the primary recording unit set, and the count value of such storage row is the only count value in the primary recording unit set that satisfies the first numerical condition, the count value of such storage row may be directly determined to satisfy the first access condition, without further verification based on the first time condition.

If the count value of the storage row does not satisfy the first numerical condition, the count value of such storage row may be directly determined to not satisfy the first access condition.

The first numerical condition may be a condition configured to characterize that the count value corresponding to the number of accessed times of the storage row is the lowest in all count values recorded in the primary recording unit set. For example, the first numerical condition may be, but may be not limited to, configured to be one of following conditions 1-1 to 1-3.

For the condition 1-1, the count value of the number of accessed times of corresponding storage row may be the minimum value in all count values recorded in the primary recording unit set.

For the condition 1-2, the count value of the number of accessed times of corresponding storage row may be the top_k1 value in ascending order of all count values recorded in the primary recording unit set.

In one embodiment, 1≤k1<n, where n is the number of primary recording units in the primary recording unit set, and k1 and n are both integers.

For the condition 1-3, the count value of the number of accessed times of corresponding storage row may be less than a count threshold configured.

The first time condition may be a condition configured to characterize that the latest access time of corresponding storage row may be the earliest latest access time in the storage rows corresponding to the primary recording units in the primary recording unit set. For example, the first time condition may be, but may be not limited to, configured to be one of following conditions 2-1 to 2-3.

For the condition 2-1, the latest access time of corresponding storage row may be the earliest or minimum latest access time in all storage rows corresponding to the information recorded in the primary recording unit set.

For the condition 2-2, the latest access time of corresponding storage row may be the top_k2 in ascending sequence of the latest access times (i.e., time points) in all storage rows corresponding to the information recorded in the primary recording unit set.

In one embodiment, 1≤k2<n, where k2 is an integer, and the definition of n may refer to the description above.

Ascending sequence of the latest access times may refer to the sequence obtained by sorting the latest access times of all storage rows corresponding to the information recorded in the primary recording unit set in chronological order.

For a condition 2-3, the latest access time of corresponding storage row may be earlier than a time threshold configured.

In practical applications, the time threshold may be adjusted periodically or irregularly over time.

Combining the first numerical condition and the first time condition described above, in an implementation, the first access condition may be optionally configured as that the count value of the number of accessed times of corresponding storage row may be the minimum value in the count values recorded in the primary recording unit set; and when multiple primary recording units satisfy such minimum value, the latest access time of corresponding storage row may be the earliest/minimum latest access time in the storage rows corresponding to the information recorded in the primary recording unit set.

Based on the first access condition configured, the row information of the storage rows recorded in the primary recording unit set may be replaced based on access frequency, access time, and other dimensions; the row information of the storage rows with low access frequency and early access time (old) may be replaced first; the row information of the storage rows with high access frequency and recent access time (new) may be retained in the primary recording unit set, which may be convenient to accurate obtain the access status of the storage rows retained in the primary recording unit set. Based on the row information of retained storage rows (row addresses, current count value of the number of accesses and the like), whether adjacent rows of such storage rows need to be refreshed may be precisely determined.

During an implementation, the maximum number of storage rows that may be accessed or the most common number of rows that may be accessed in same time-period may be combined with actual usage scenario of the storage component; and the number of primary recording units included in the primary recording unit set may be configured based on the maximum number of storage rows that may be accessed or the most common number of rows that may be accessed in same time-period. In such way, the primary recording units provided by the primary recording unit set may satisfy accurate recording needs of the access status of multiple storage rows in the scenario that the access time of multiple storage rows may be same or similar, thereby being convenient for accurate determination of whether adjacent rows of such storage rows need to be refreshed.

More primary recording units may satisfy the need to record more storage row information, and correspondingly, may process the record of accessed information of more frequently accessed storage rows, but may increase resource overhead. In practical applications, the number of primary recording units in the primary recording unit set may be configured based on comprehensive consideration of performance and resource overhead.

Based on the refresh management characteristic of RFM, that is, “frequent access to same row of the storage component, such as the DDR memory chip or the like, may cause bit flip phenomenon in adjacent rows, known as row hammer (RH); and to ensure the accuracy of data in adjacent rows, additional refresh processing may be needed for adjacent rows”, it can be known that highly active, frequently accessed storage rows may need to be selected for additional refresh management of corresponding neighbor rows. Above-mentioned mechanism for recording and replacing storage row information by combining access frequency dimension and time dimension provided in embodiments of the present disclosure may be consistent with access-operation-based refresh needs of the storage rows in the storage component, which may be convenient for filtering out low-active storage rows and promptly selecting highly active, recently accessed storage rows for additional refresh management of corresponding neighbor rows.

Furthermore, unlike the LFU replacement algorithm in existing technologies, when the row address of the first row is not currently recorded and no idle primary recording unit exists in the primary recording unit set, in embodiments of the present disclosure, the original row information in the first recording unit may not be discarded after replacing the row information in the first recording unit with the row information corresponding to the first row. Instead, the original row information in the first recording unit may be written to corresponding auxiliary recording unit in the auxiliary recording unit set, and certain original row information most recently replaced may continue to be recorded. Based on such configuration, after the original row information in the first recording unit is replaced, the original row information in the first recording unit may be not immediately cleared, thereby supporting that the accessed information of the storage row may be updated based on the original row information when the storage row characterized by the original row information is accessed within a subsequent period-time. For example, the number of accessed times of the storage row may be accumulated based on the original count value in the original row information and the like. In such way, it may more objectively and accurately reflect the access status of the storage row characterized by the replaced original row information. When frequent access events to the replaced storage row occur within a short period of time, refresh management accuracy of adjacent rows of the replaced storage row may be ensured as possible.

In addition, above-mentioned configuration may also prevent that when the row information of two or more storage rows satisfies the replacement condition and the two or more storage rows are frequently accessed alternately, corresponding access count value and the like after each replacement may be cleared to 0 each time, the access count value may change to 1 after one access, and the access count value may be replaced and cleared to 0 again when another storage row is accessed again, which may result in that the row information of two or more storage rows is frequently replaced and the access count is always minimum. Correspondingly, accurate information on the access status of the frequently accessed storage rows in above scenario may be obtained, thereby being conveniently to accurately determine whether adjacent rows of the frequently accessed storage rows need to be refreshed.

As disclosed above, for the processing method provided by embodiments of the present disclosure, the primary recording unit set and the auxiliary recording unit set for storing row information (including row addresses and accessed information) may be configured for the storage component in advance; and corresponding storage and replacement mechanism may be configured for the primary recording unit set and the auxiliary recording unit set. Based on above-mentioned storage and replacement mechanism, the row information of the frequently accessed or recently accessed (newly accessed) highly-active storage rows may be stored in the primary recording unit set, thereby being convenient for accurately obtain the access status of such storage rows and further accurately determining whether the neighbor rows of such storage rows need to be refreshed. Furthermore, the row information recently replaced from the primary recording unit set may be written into corresponding auxiliary recording unit in the auxiliary recording unit set, which may prevent the replaced row information from being immediately cleared and support that accessed information may be updated based on the original row information replaced when the storage row characterized by the replaced row information is accessed. Correspondingly, when frequent access events to the replaced storage row occur subsequently, refresh management accuracy of adjacent rows of the replaced storage row may be ensured as possible.

Therefore, the present disclosure may reduce the problem in existing techniques that the row address targeted by RFM refresh may be difficult to accurately and optimally determine the rows needs to be actually refreshed, thereby desirably satisfying refresh needs for the rows adjacent to frequently accessed rows.

In an optional embodiment, the processing method provided by the present disclosure may further include following processing.

At one operational step, in response to that the row address of the first row is not recorded, and an idle primary recording unit exists in the primary recording unit set, the row information corresponding to the first row may be written to the idle primary recording unit.

In such scenario, for example, the row address of the first row and currently-accessed information, such as current access count, access frequency, and frequency level, may be written to the idle primary recording unit for recording.

No historical storage information of the first row may be in the primary recording unit set in such scenario; and correspondingly no historical count value in the primary recording unit set. Therefore, currently-accessed information of the first row may be generated directly based on currently detected access operation to the first row. For example, corresponding count value of the number of accessed times of the first row, the access frequency or the frequency level, may be generated. Assuming the starting count value is 0 and the count increments by 1 for each access, current count value of the number of accessed times of the first row is 1. Accordingly, the row address of the first row and current access count value “1” may be stored in the first recording unit. The configuration strategy of the access frequency, the frequency level and the like may be the information of the access frequency, the frequency level and the like accordingly determined by the number of accesses 1.

At another operational step, in response to that the row address of the first row is recorded and further recorded in the first auxiliary recording unit of the auxiliary recording unit set, the row information in the first auxiliary recording unit and the second primary recording unit may be switched, and the accessed information of the first row in the second primary recording unit may be updated based on the original accessed information of the first row and the access operation.

The row information recorded in the second primary recording unit may satisfy the first access condition. The details of the first access condition may refer to above-mentioned description and may be not described in detail herein.

When updating the accessed information of the first row in the second primary recording unit based on the original accessed information of the first row and the access operation, for example, according to configured count increment value corresponding to single access operation, the increment value may be accumulated on the original count value of the number of accessed times of the first row based on current access operation. Furthermore, based on corresponding policy, information such as the access frequency, the frequency level and the like of the first row may be updated according to current access operation to the first row.

In practical applications, the row information of the first row may be updated (e.g., by incrementing corresponding count value by 1) before performing the information exchange operation, and updated row information may be written to the second primary recording unit. Or the row information of the first row already written to the second primary recording unit may be updated (e.g., by incrementing corresponding count value by 1) after performing the information exchange operation, which may be not limited in the present disclosure.

Still at another operational step, in response to that the row address of the first row is recorded and further recorded in the third primary recording unit of the primary recording unit set, currently-accessed information in the third primary recording unit may be updated based on the access operation.

In such scenario, for example, based on current access operation to the first row, the accessed information of the first row recorded in the third primary recording unit may be updated. For example, the number of accessed times may be accumulated (e.g., by adding 1) based on the access count value in the third primary recording unit.

Furthermore, based on corresponding policy, information such as the access frequency, the frequency level and the like of the first row may be updated according to current access operation to the first row.

In one embodiment, the storage and replacement mechanism for the primary recording unit set and the auxiliary recording unit set may be further improved. By detecting the access operations to the storage rows in the storage space of the storage component and, in response to detecting the access operations to corresponding rows (e.g., the first row), the row information of corresponding row may be recorded in the primary recording unit based on the storage and replacement mechanism, thereby being convenient for accurately obtaining the access status of frequently accessed or recently accessed (newly accessed) highly-active storage rows, and further being convenient for precise determination of whether adjacent rows of such storage rows need to be refreshed. Furthermore, the row information replaced from the primary recording unit may be written to corresponding auxiliary recording unit in the auxiliary recording unit set, which may prevent replaced row information from being immediately cleared. Therefore, when the storage row characterized by the replaced row information is subsequently accessed within a relatively short period of time, it may realize that the accessed information for the replaced row may be updated based on the original row information. Correspondingly, when frequent access events occur to the replaced storage row, current recorded information may still accurately reflect the access status of the replaced storage row, thereby ensuring refresh management accuracy of adjacent rows of the replaced storage row as possible.

In an optional embodiment, in exemplary step 102 of the method provided in embodiments of the present disclosure, writing the original row information in the first recording unit to corresponding auxiliary recording unit in the auxiliary recording unit set may be implemented by writing the original row information in the first primary recording unit to the second auxiliary recording unit that satisfies the second access condition.

When writing the original row information in the first primary recording unit to the second auxiliary recording unit that satisfies the second access condition, in response to that the second auxiliary recording unit is not idle, the original row information recorded in the second auxiliary recording unit may be cleared first.

In one embodiment, corresponding auxiliary recording unit satisfying the second access condition may indicate that writing the row information of the storage row to corresponding auxiliary recording unit may be allowed.

Optionally, the second access condition may include a condition a and a condition b.

The condition a may be that the auxiliary recording unit is idle. Or the condition b may be that the count value of corresponding storage row is a count value satisfying the second numerical condition in the count value recorded in the auxiliary recording unit set; and in response to that multiple count values satisfy the second numerical condition, the count value of corresponding storage row is a count value satisfying the second time condition in multiple count values satisfying the second numerical condition.

Based on above-mentioned second access condition, priority may be configured between condition a and condition b. Optionally, the condition a may have higher priority than condition b. Therefore, the condition a may first be configured to determine whether an idle auxiliary recording unit exists in the auxiliary recording unit set. If the idle auxiliary recording unit exists in the auxiliary recording unit set, the condition b may be not further configured for determination, and the original row information in the first primary recording unit may be directly written to the idle auxiliary recording unit. Conversely, in response to that no idle auxiliary recording unit exists, the condition b may be further configured for determination. For example, the second auxiliary recording unit satisfying the condition b may be determined from the auxiliary recording unit set, and the original row information in the first primary recording unit may be written to determined second auxiliary recording unit.

Obviously, practical applications may be not limited to above description. Both the condition a and the condition b may be configured for determination, which may only need to satisfy that the auxiliary recording unit satisfies either condition, the auxiliary recording unit may be determined to satisfy the second access condition.

The second numerical condition may be a condition configured to characterize that the count value characterizing the number of accessed times of corresponding storage row is the lowest in the count values recorded in the auxiliary recording unit set. For example, the second numerical condition may be, but may be not limited to, one of following conditions 4-1 to 4-3.

For the condition 4-1, the count value of the number of accessed times of corresponding storage row may be the minimum value in the count values recorded in the auxiliary recording unit set.

For the condition 4-2, the count value of the number of accessed times of corresponding storage row may be the top_k3 in ascending sequence of the count values recorded in the auxiliary recording unit set.

In one embodiment, 1≤k3<n, where n is the number of primary recording units in the primary recording unit set, and k3 and n are both integers.

For the condition 4-3, the count value of the number of accessed times of corresponding storage row may be less than a count threshold configured.

The second time condition may be a condition configured to characterize that the latest access time of corresponding storage row may be the earliest in the latest access times of the storage rows corresponding to the information recorded in the auxiliary recording unit set. For example, the second time condition may be, but may be not limited to, one of following conditions 5-1 to 5-3.

For the condition 5-1, the latest access time of corresponding storage row may be the earliest/minimum in the latest access times of the storage rows corresponding to the information recorded in the auxiliary recording unit set.

For the condition 5-2, the latest access time of corresponding storage row may be the top_k4 in ascending sequence of the latest access times of the storage rows corresponding to the information recorded in the auxiliary recording unit set.

In one embodiment, 1≤k4<n, where k4 is an integer, and the definition of n may refer to the description above.

Ascending sequence of the latest access times may refer to the sequence obtained by sorting the latest access times of all storage rows corresponding to the information recorded in the primary recording unit set in chronological order.

For the condition 5-3, the latest access time of corresponding storage row may be earlier than a time threshold configured.

In actual applications, the time threshold may be adjusted periodically or irregularly over time.

The number of auxiliary recording units in the auxiliary recording unit set may correspond to the time length that the recording of replaced row information in the primary recording unit is delayed and correspond to the number of conflict storage rows that may be resolved due to frequent alternating access. The larger the number of auxiliary recording units in the auxiliary recording unit set, the longer the time length that the recording of replaced row information in the primary recording unit is delayed, and the greater the number of conflict storage row that may be resolved due to frequent alternating access. Conversely, the smaller the number of auxiliary recording units in the auxiliary recording unit set, the shorter the time length that the recording of replaced row information in the primary recording unit is delayed, and the smaller the number of conflict storage row that may be resolved due to frequent alternating access. For example, in response to that the number of auxiliary recording units is 2, when three storage rows are frequently alternating accessed, the conflict recording problem that three storage rows are replaced due to frequently alternating access may be resolved, which may ensure that the row information of these three storage rows may be correctly recorded and prevent the count value from being reset to zero due to frequent alternating access, thereby further affecting refresh management accuracy.

It may be understood that a larger number of auxiliary recording units may handle more row information recording problems during alternate access of the storage rows; and the time length that the recording of replaced row information in the primary recording unit is delayed may be longer, and resource overhead may be increased. In practical applications, the number of auxiliary recording units may be appropriately configured based on the combination of factors, such as performance and resource overhead.

In one embodiment, the storage and replacement mechanism for primary recording unit set and the auxiliary recording unit set may be further improved. For the row information of the storage row replaced from the primary recording unit set, the second auxiliary recording unit satisfying the second access condition may be determined from the auxiliary recording unit set; and the row information of the replaced storage row from the primary recording unit set may be written to the second auxiliary recording unit satisfying the second access condition. On one hand, the row information of the replaced storage row may be prevented from being cleared from the primary recording unit set; and when such storage row is accessed subsequently, it may support that accessed information may be updated based the original row information of such storage row, thereby ensuring accurate refresh management of adjacent rows of the storage row. On the other hand, the row information replaced/cleared from the auxiliary recording unit set may be ensured to correspond to low active storage rows. Accordingly, the storage rows corresponding to such-type information may be the storage rows having no or low refresh needs. Therefore, clearing out the row information of such-type storage rows in the auxiliary recording unit may not cause adverse effect on the refresh management of the storage rows.

FIG. 2 illustrates another flow chart of a processing method according to various embodiments of the present disclosure. In an optional embodiment, referring to the processing method flow chart shown in FIG. 2, the processing method provided by the present disclosure may further include following exemplary steps.

At 103, in response to that currently-accessed information of the second row in the primary recording unit set satisfies a target condition, target refresh processing may be performed on adjacent rows of the second row.

The target condition may be a condition configured to characterize that frequent accesses to corresponding storage row require refreshing adjacent rows of corresponding storage row. The target condition may be, but may be not limited to, configured to be at least one of the following: current count value of the number of accessed times of corresponding storage row reaches a count threshold, current access frequency degree of corresponding storage row reaches a degree threshold configured, or current access frequency level of corresponding storage row reaches a level threshold configured.

In actual applications, currently-accessed information of each storage row recorded in the primary recording unit set may be detected to determine whether currently-accessed information satisfies the target condition; and in response to that currently-accessed information of the second row in the primary recording unit set satisfies the target condition, target refresh processing may be triggered on adjacent rows of the second row.

When performing the target refresh on adjacent rows of the second row, a refresh instruction including the row address of the second row and target operation information may be first generated. For example, in response to that the count value corresponding to the number of accessed times of the second row in the primary recording unit set reaches a threshold, a refresh instruction including the row address of the second row and target operation information may be generated; and the target operation information may indicate the refresh operation corresponding to the target refresh.

Next, according to the row address of the second row and a preset number of adjacent rows, the target adjacent rows of the second row to be refreshed may be determined. Assuming the preset number of adjacent rows is x, x adjacent storage rows preceding and/or x adjacent storage rows following the second row may be determined as the target adjacent rows of the second row to be refreshed. The terms “adjacent” or “neighboring” between different storage rows may refer to that row addresses of different storage rows are adjacent or neighboring to each other.

Based on the above, the refresh operation indicated by the target operation information may be further performed on the target adjacent rows corresponding to the second row.

In an optional embodiment, the refresh operation indicated by the target operation information may refer to refreshing all storage rows in the target adjacent rows corresponding to the second row.

However, the refresh operation indicated by the target operation information may also refer to refreshing a portion of the target adjacent rows corresponding to the second row, while probabilistically refreshing another portion of remaining target adjacent rows. Probabilistically refreshing the storage rows may indicate refreshing the storage row according to a certain probability.

For example, assuming the preset number of adjacent rows is 2, the rows immediately preceding and following the second row (i.e., the storage rows indicated by row addresses obtained using the second row's row address row_addr±1) may be refreshed, and probabilistically refreshing may be performed on the rows immediately preceding and following the second row (i.e., the storage rows indicated by row addresses obtained using the second row's row address row_addr±2) according to set probability.

For DRFM, DRFM performance and related characteristic parameters may support the usage of the MR (mode register) configuration, which may include, but may be not limited to, determining whether current storage component, such as memory chip, supports DRFM based on the MR configuration, whether BRC (bounded refresh configuration) is enabled if DRFM is supported, and what is configured BRC value if BRC is enabled. The BRC value may represent the refresh boundary and may be configured as the preset number of adjacent rows. For example, for the second row, BRC=2 may indicate that the rows immediately preceding, following, and next-adjacent to the second row may need to be refreshed. For example, the storage rows indicated by the row address obtained using the second row's row address row_addr±1 may be refreshed, and the storage rows indicated by the row address obtained using the second row's row address row_addr±2 may be probabilistically refreshed.

After performing the target refresh on the target adjacent rows corresponding to the second row, the accessed information in the row information corresponding to the second row may also be reset to zero, and the accessed information of the second row may be updated from zero.

For example, the access count of the second row may be reset to zero. Subsequently, when the access operation of the second row is detected, the number of accessed times of the second row may be counted from zero in response to the detection of the access operation.

In one embodiment, refresh operations may be performed on adjacent rows of the determined storage row, and the refresh needs of adjacent rows of the frequently accessed rows may be satisfied, thereby effectively ensuring the data accuracy of adjacent rows of the frequently accessed rows. Furthermore, the accessed information of corresponding storage row may be reset to zero after performing refresh processing on adjacent rows of corresponding storage row, thereby effectively ensuring the accuracy of the accessed information (e.g., the count information of the number of accessed times) of each storage row after each refresh processing and correspondingly ensuring refresh management accuracy of adjacent rows of each storage row.

In an optional embodiment, an application example of the method of the present disclosure is provided. In one embodiment, the storage component may be a memory chip, such as a DDR memory chip. Each memory chip may include multiple banks. Each bank in the memory may be a logical storage region including multiple storage rows.

In one embodiment, the refresh processing of the storage rows in the memory chip may be based on DRFM.

Optionally, in one embodiment, the DRFM may use bank as granularity (e.g., the bank is used as the smallest unit or the smallest granularity for division or configuration) and provide an independent refresh engine module (DRFM Engine) for each bank. Refresh management of the storage rows in each bank of the memory chip may be achieved through collaboration between a memory controller (e.g., DDRC (DDR Controller)) and a DRFM Engine.

In one embodiment, the bank configured as granularity may be that 4 primary recording units and 2 auxiliary recording units may be configured for each bank, which may record the row address (row_addr) and the count value of the number of accessed times of corresponding row within the bank.

Each time the DDRC executes a memory row access command, DDRC may record or update the row information of the accessed row in corresponding bank's primary recording unit based on the processing method provided in the present disclosure. For example, the row address (row_addr) and the count value of the number of accessed times of the accessed row may be recorded, or the count value of the number of accessed times of the accessed row may be updated. Optionally, the DRFM Engine may detect the count values of the number of accessed times for different rows within each primary recording unit. Once the DRFM Engine detects that the count value of the number of accessed times of the row corresponding to a row_addr reaches a threshold, the DRFM Engine may report the row_addr that reached the threshold to the DDRC. The DDRC may generate a DRFM refresh command including the reported row_addr and required “refresh” action and send the command to the memory chip such as DDR chip or the like. The memory chip such as the DDR chip or the like may read the BRC and the refresh command to perform refresh processing on the rows preceding and following the row specified by the DRFM command.

Assuming the interval between two RFM refreshes in the memory chip such as the DDR or the like is tREFI=3.906 us, and the minimum time interval between two ACTs (ACT may refer to access operation, and two ACTs may refer to two access operations to same memory row) on same memory row is minimum time=60 ns, the maximum number of ACTs between two RFM refreshes may be max_num≈64. Each bank may use four primary recording units to record the number of ACTs executed for corresponding row address. The primary recording unit with the highest current access count value may be marked; and the row_addr with the smallest and earliest (herein, earliest may refer to the time when current count value corresponding to the row_addr appeared earliest) and corresponding number of ACTs may be marked. Meanwhile, two auxiliary recording units may be also configured to record two most recently replaced row_addr from the primary recording unit and corresponding number of ACTs. Each primary recording unit or each auxiliary recording unit may record information of one memory row at a time. If the number of row_addr to be recorded by the primary recording unit exceeds four, the auxiliary recording unit may be needed to perform the replacement.

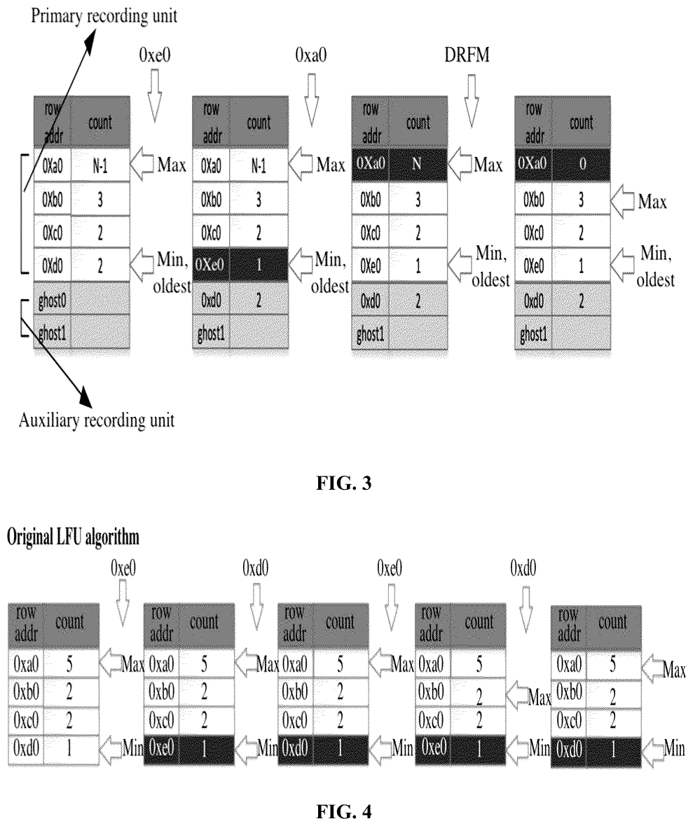

The replacement method may be optimized based on the LFU algorithm. Referring to FIG. 3, following exemplary operational steps may be performed.
1) The access operation of the storage row in the bank may be detected.
2) In response to that the access operation of the first row in the bank is detected, when the row address of the first row is not recorded and an idle primary recording unit exists, the row_addr of the first row and the count value of 1 of the number of accessed times may be written to the idle primary recording unit.
3) In response to that the row_addr of the first row is not recorded, but no idle primary recording unit exists, the primary recording unit with the smallest number of ACTs may be selected. In response to that there are multiple primary recording units with the smallest number of ACTs, the primary recording unit with the row_addr whose current count value appears earliest may be selected, and the row information of the first row may be written to such primary recording unit.

Referring to FIG. 3, the non-grayed recording units may be primary recording units, and the grayed recording units may be auxiliary recording units. Max may represent the primary recording unit with the highest current access count value; Min may represent the primary recording unit with the lowest current access count value; and “Min, oldest” may represent the primary recording unit with the lowest current access count value and the earliest access count time in the primary recording units with the lowest count value (i.e., the earliest occurrence of current count value). For the new address 0xe0 to be written to the primary recording unit, the address 0xd0 with the smallest and earliest ACT value may be selected for replacement. The replaced address 0xd0 and corresponding ACT value may be recorded in the auxiliary recording unit, such as in the auxiliary recording unit ghost0.
4) In response to that the row_addr of the first row is recorded and exists in the primary recording unit, the count value in the primary recording unit where the row_addr of the first row is located may be directly incremented by 1.

For example, in response to that the access operation of the storage row characterized by address 0xa0 is detected, the access count value may be incremented based on original count value of the address 0xa0.
5) In response to that the row_addr of the first row is recorded but exists in the auxiliary recording unit, the primary recording unit with the “Min” or “Min, oldest” mark may be selected to exchange information with the auxiliary recording unit including the row_addr of the first row, and the count value of the first row may be incremented by 1.
6) When the access count value for a row (e.g., the number of accesses of row_addr=0xa0) reaches the DRFM threshold N, the DRFM engine module corresponding to such bank may feedback the row_addr=0xa0 to the DDRC; the DDRC may send a DRFM command including the row_addr=0xa0 and needed “refresh” operation to the DDR; based on such command and the BRC value, the DDR may refresh adjacent rows of the row_addr=0xa0; and after the refresh is complete, the count value corresponding to the address 0xa0 may be reset to zero.

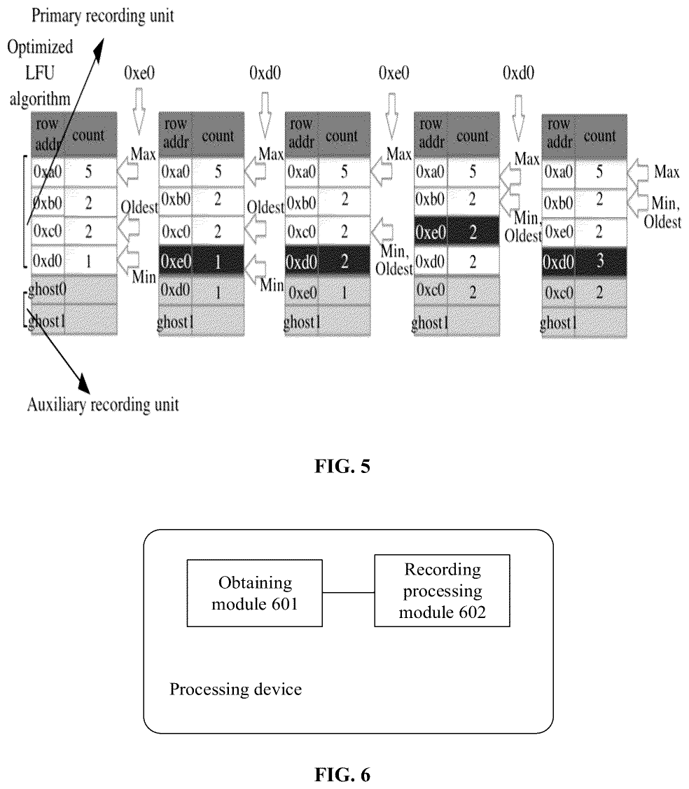

For the scenario that the ACT commands (i.e., data access commands) are executed alternately on two or more storage rows, and the access count value corresponding to the storage row where the ACT commands are executed alternately has the smallest access count value, FIGS. 4 and 5 may be taken as an example to illustrate the advantages of the solution of embodiments of the present disclosure (corresponding to FIG. 5) over the LFU algorithm in the existing technology (corresponding to FIG. 4).

In existing LFU algorithm, no auxiliary recording unit may exist; and accordingly, the concept of primary and auxiliary recording units may not exist. When the number of row_addr to be recorded in the recording unit exceeds the number of recording units, such as 4, recorded row information may need to be replaced. In one embodiment shown in FIG. 4, it is assumed that the storage rows corresponding to row addresses 0xd0 and 0xe0 are accessed alternately, the row information corresponding to row_addr=0xd0 and row_addr=0xe0 may need to be continuously replaced in the recording units. As a result, two row_addr 0xd0 and 0xe0 may be continuously replaced in the recording units, and corresponding count value may be always 1 (each replacement may be equivalent to clearing original count value, causing the count to restart from 0), which may be obviously inconsistent with actual situation that the rows corresponding to 0xd0 and 0xe0 are frequently accessed. Accordingly, the counting results of the number of accessed times of the rows corresponding to 0xd0 and 0xe0 may be inconsistent with actual situation, which may be difficult to satisfy the refresh needs of adjacent rows corresponding to frequently accessed rows 0xd0/0xe0.

In embodiments based on the provided processing method of the present disclosure, referring to FIG. 5, in addition to four primary recording units (the non-grayed recording units in FIG. 5), two auxiliary recording units (the grayed recording units in FIG. 5) may be further added to record the row_addr that was recently replaced from the primary recording unit and corresponding access count value.

For the scenario that the storage rows corresponding to row addresses 0xd0 and 0xe0 are accessed alternately, referring to FIG. 5, when the access operation of the corresponding row 0xe0 causes the address 0xe0 to need to be recorded for the first time, the row information corresponding to the address 0xe0 may be configured to replace the row information corresponding to the address 0xd0 in the primary recording unit marked with “Min” (i.e., the smallest count value), and the address 0xd0 and corresponding count value may be transferred and recorded in the auxiliary recording unit. Next, when the row corresponding to 0xd0 is accessed again which may cause 0xd0 need to be recorded in the primary recording unit, the count value corresponding to 0xd0 in the auxiliary recording unit may be incremented by 1 and then 0xe0 and count value in the primary recording unit may be replaced. When the row corresponding to 0xe0 is accessed again, the count values in the primary recording units may be compared, and 0xc0 which is the smallest and reaches 2 the earliest may be selected for replacement; and 0xc0 and corresponding count value may be transferred to the auxiliary recording unit for recording. At this point, 0xb0 may become the row_addr with the smallest and earliest value which may be used as next replacement target. Compared to the LFU algorithm in existing technology, in one embodiment, based on four primary recording units, the row information of the storage rows corresponding to 4 row_addr, which most frequently execute ACT commands, may be accurately recorded. Furthermore, in one embodiment, based on two auxiliary recording units, the problem of count value deviation caused by the rows corresponding to 2 row_addr being frequently accessed but constantly replaced may be solved. In one embodiment of FIG. 5, the auxiliary recording unit ghost1 may be idle and inactive. In other words, two auxiliary recording units may address the problem of the rows corresponding to 3 row_addr being accessed alternately and requiring constant replacement of recorded row information, thereby effectively satisfying the refresh needs for adjacent rows of such frequently accessed rows.

Corresponding to above-mentioned processing method, embodiments of the present disclosure further provide a processing device. The structure of the processing device is shown in FIG. 6. The processing device may include an obtaining module 601, configured to, in response to that the access operation of the first row in the storage space of the storage component is detected, obtain the row address of the first row; and further include a recording processing module 602, configured to, in response to that the row address of the first row is not recorded and no idle primary recording unit exists in a primary recording unit set, replace the row information in the first recording unit with the row information corresponding to the first row, and write original row information in the first recording unit to corresponding auxiliary recording unit in an auxiliary recording unit set, where the row information recorded in the second primary recording unit may satisfy the first access condition

The original row information recorded in the first primary recording unit may satisfy the first access condition; and the row information in corresponding primary recording unit satisfying the first access condition may characterize that replacement of the row information in corresponding primary recording unit is allowed. Each recording unit in the primary recording unit set and the auxiliary recording unit set may be configured to record row information of corresponding storage row in the storage space of the storage component. The row information may include a row address and currently-accessed information for the storage row indicated by the row address. Currently-accessed information may be configured to determine whether refresh operation is needed for adjacent rows of corresponding storage row.

In an optional embodiment, the recording processing module 602 may be further configured to, in response to that the row address of the first row is not recorded, and an idle primary recording unit exists in the primary recording unit set, write the row information corresponding to the first row to the idle primary recording unit.

In an optional embodiment, the recording processing module 602 may be further configured to, in response to that the row address of the first row is recorded and further recorded in the first auxiliary recording unit of the auxiliary recording unit set, switch the row information in the first auxiliary recording unit and the second primary recording unit, and update the accessed information of the first row in the second primary recording unit based on the original accessed information of the first row and the access operation; and in response to that the row address of the first row is recorded and further recorded in the third primary recording unit of the primary recording unit set, update currently-accessed information in the third primary recording unit based on the access operation.

In an optional embodiment, currently-accessed information stored in each primary recording unit may include the current count value of the number of accessed times of a corresponding storage row.

The first access condition may include that the count value of corresponding storage row is a count value satisfying the first numerical condition in multiple count values recorded in the primary recording unit set; and in response to that multiple count values satisfy the first numerical condition, the count value of corresponding storage row is a count value satisfying the first time condition in multiple count values satisfying the first numerical condition.

In an optional embodiment, when writing the original row information in the first recording unit to corresponding auxiliary recording unit set, the recording processing module 602 may be configured to write the original row information in the first primary recording unit to the second auxiliary recording unit that satisfies the second access condition.

Correspondingly, the auxiliary recording unit satisfying the second access condition may characterize that writing the row information of the storage row to be recorded to corresponding auxiliary recording unit is allowed.

In an optional embodiment, currently-accessed information stored in each primary recording unit may include the current count value of the number of accessed times of corresponding storage row.

The second access condition may include the auxiliary recording unit is idle; or the count value of corresponding storage row is a count value satisfying the second numerical condition in the count value recorded in the auxiliary recording unit set; and in response to that multiple count values satisfy the second numerical condition, the count value of corresponding storage row is a count value satisfying the second time condition in multiple count values satisfying the second numerical condition.

In an optional embodiment, above-mentioned device may further include a refresh processing module, configured to perform the target refresh processing on adjacent rows of the second row in response to that currently-accessed information of the second row in the primary recording unit set satisfies the target condition.

In an optional embodiment, when performing the target refresh processing on adjacent rows of the second row in response to that currently-accessed information of the second row in the primary recording unit set satisfies the target condition, the refresh processing module may be configured to: in response to that the count value corresponding to the number of accessed times of the second row in the primary recording unit set reaches a threshold, generate a refresh instruction including the row address of the second row and target operation information, where the target operation information may indicate the refresh operation corresponding to the target refresh; according to the row address of the second row and a preset number of adjacent rows, determine the target adjacent rows of the second row to be refreshed; and perform the refresh operation indicated by the target operation information on the target adjacent row.

In an optional embodiment, above-mentioned device may further include a clearing module, configured to, after performing the target refresh processing on adjacent rows of the second row, reset the accessed information in the row information, corresponding to the second row, to zero, and update the accessed information of the second row from zero.

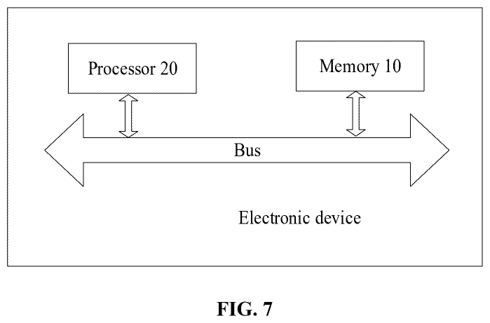

Embodiments of the present disclosure further provide an electronic device. The compositional structural of the electronic device is shown in FIG. 7. The electronic device may at least include a memory 10 for storing a computer instruction set, where the computer instruction set may be implemented in the form of a computer program; and further include a processor 20, configured to implement the processing method provided in any of the above method embodiments by executing the computer instruction set.

The processor 20 may be a central processing unit (CPU), an application-specific integrated circuit (ASIC), a digital signal processor (DSP), an application-specific integrated circuit (ASIC), a field-programmable gate array (FPGA), a neural network processor (NPU), a deep learning processor (DPU), or other programmable logic devices.

The electronic device may include a display device and/or a display interface, capable of connecting to an external display device.

Optionally, the electronic device may further include a camera assembly and/or may be connected to an external camera assembly.

Furthermore, the electronic device may further include components such as a communication interface and a communication bus. The memory, the processor, and the communication interface may communicate with each other via a communication bus.

The communication interface may be configured for communication between the electronic device and other devices. The communication bus may be a peripheral component interconnect (PCI) bus, an extended industry standard architecture (EISA) bus and/or the like. The communication buses may be divided into an address bus, a data bus, a control bus, and the like.

Various embodiments of the present disclosure provide an electronic device. The electronic device includes a memory, configured to store a computer program; and one or more processors, configured to, when the computer program is executed, perform a processing method. The processing method includes in response to that an access operation of a first row in a storage space of a storage component is detected, obtaining a row address of the first row; and in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set. Original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

Various embodiments of the present disclosure provide a non-transitory computer-readable storage medium containing a computer program that, when being executed, causes one or more processors to perform a processing method. The processing method includes in response to that an access operation of a first row in a storage space of a storage component is detected, obtaining a row address of the first row; and in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set. Original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

It should be noted that each embodiment in the present disclosure may be described in a progressive manner, and each embodiment may focus on differences from other embodiments. Same or similar parts between embodiments may be referred to each other.

For the convenience of description, above system, apparatus or device may be described in various modules or units according to functions. Obviously, when implementing the present disclosure, the function of each unit may be implemented in same or multiple software and/or hardware.

It may be seen from above description of implementation manners that those skilled in the art may clearly understand that the present disclosure may be implemented by means of software plus necessary general hardware platform. Based on such an understanding, the essence or a part making creative contribution of the technical solution of the present disclosure may be embodied in the form of a software product. The software product may be stored in a storage medium, such as ROM/RAM, a disk, an optical disk and/or the like; and may include a plurality of instructions to enable a computer device (which may be a personal computer, a server, a network device or the like) to execute the methods described in various embodiments or certain parts of embodiments of the present disclosure.

It should also be noted that in the present disclosure, relational terms such as first, second, third, fourth and the like may be merely configured to distinguish one entity or operation from another entity or operation and may not necessarily require or imply any such actual relationship or order between these entities or operations. Moreover, the terms “include”, “contain” or any other variations thereof may be intended to cover non-exclusive inclusion, such that a process, method, article, or equipment that includes a series of elements may not only include those elements, but also other elements that are not explicitly listed; or also include elements inherent to the process, method, article, or equipment. If there are no more restrictions, the elements defined by the sentence “include a . . . ” may not exclude the existence of other same elements in the process, method, article, or equipment including the elements.

The above may be merely optional implementation manners of the present disclosure. It should be noted that those skilled in the art may may make certain improvements and modifications without departing from the principles of the present disclosure. Above-mentioned improvements and modifications should also be regarded as the scope of protection of the present disclosure.

What is claimed is:

1. A processing method, comprising:
in response to that an access operation of a first row in a storage space of a storage component is detected, obtaining a row address of the first row; and
in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set, wherein:
original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

2. The method according to claim 1, further including:
in response to that the row address of the first row is not recorded, and an idle primary recording unit exists in the primary recording unit set, writing the row information corresponding to the first row into the idle primary recording unit.

3. The method according to claim 1, further including:
in response to the row address of the first row being recorded and further being recorded in a first auxiliary recording unit of the auxiliary recording unit set, switching row information in the first auxiliary recording unit with row information in a second primary recording unit, and based on the access operation, updating an accessed information of a first row in the second primary recording unit according to original accessed information of the first row, wherein row information recorded in the second primary recording unit satisfies the first access condition; and
in response to the row address of the first row being recorded and further being recorded in a third primary recording unit of the primary recording unit set, updating currently-accessed information in the third primary recording unit based on the access operation.

4. The method according to claim 1, further including:
currently-accessed information stored in each primary recording unit includes a current count value of a number of accessed times of a corresponding storage row; and
the first access condition includes that a count value of the corresponding storage row is a count value satisfying a first numerical condition in all count values recorded in the primary recording unit set, and in response to a plurality of count values satisfying the first numerical condition, the count value of the corresponding storage row is a count value that satisfies a first time condition in the plurality of count values satisfying the first numerical condition.

5. The method according to claim 1, wherein writing the original row information in the first recording unit to the corresponding auxiliary recording unit in the auxiliary recording unit set includes:
writing the original row information in the first primary recording unit to a second auxiliary recording unit satisfying a second access condition, wherein a corresponding auxiliary recording unit satisfying the second access condition characterizes that the row information, to be recorded, of the storage row is allowed to be written to the corresponding auxiliary recording unit.

6. The method according to claim 5, wherein:
currently-accessed information stored in each primary recording unit includes a current count value of a number of accessed times of a corresponding storage row; and
the second access condition includes that a count value of the corresponding storage row is a count value satisfying a second numerical condition in all count values recorded in the primary recording unit set, and in response to a plurality of count values satisfying the second numerical condition, the count value of the corresponding storage row is a count value that satisfies a second time condition in the plurality of count values satisfying the second numerical condition.

7. The method according to claim 1, further including:
in response to that currently-accessed information of a second row in the primary recording unit set satisfies a target condition, performing a target refresh processing on an adjacent row of the second row.

8. The method according to claim 7, wherein in response to that the currently-accessed information of the second row in the primary recording unit set satisfies the target condition, performing the target refresh processing on the adjacent row of the second row includes:
in response to that a current count value corresponding to a number of accessed times of the second row in the primary recording unit set reaches a threshold, generating a refresh instruction including a row address of the second row and target operation information, wherein the target operation information is configured to indicate a refresh operation corresponding to the target refresh processing;
based on the row address of the second row and a preset number of adjacent rows, determining a target adjacent row, corresponding to the second row, for the refresh operation to be performed; and
performing the refresh operation indicated by the target operation information on the target adjacent row.

9. The method according to claim 7, after performing the target refresh processing on the adjacent row of the second row, further including:
resetting accessed information in row information, corresponding to the second row, to zero, thereby updating the accessed information in the row information corresponding to the second row from zero.

10. An electronic device, comprising:
a memory, configured to store a computer program; and
one or more processors, configured to, when the computer program is executed, perform:
in response to that an access operation of a first row in a storage space of a storage component is detected, obtaining a row address of the first row; and
in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set, wherein:
original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

11. The electronic device according to claim 10, wherein the one or more processors are further configured to perform:
in response to that the row address of the first row is not recorded, and an idle primary recording unit exists in the primary recording unit set, writing the row information corresponding to the first row into the idle primary recording unit.

12. The electronic device according to claim 10, wherein the one or more processors are further configured to perform:
in response to the row address of the first row being recorded and further being recorded in a first auxiliary recording unit of the auxiliary recording unit set, switching row information in the first auxiliary recording unit with row information in a second primary recording unit, and based on the access operation, updating an accessed information of a first row in the second primary recording unit according to original accessed information of the first row, wherein row information recorded in the second primary recording unit satisfies the first access condition; and
in response to the row address of the first row being recorded and further being recorded in a third primary recording unit of the primary recording unit set, updating currently-accessed information in the third primary recording unit based on the access operation.

13. The electronic device according to claim 10, wherein the one or more processors are further configured to perform:
currently-accessed information stored in each primary recording unit includes a current count value of a number of accessed times of a corresponding storage row; and
the first access condition includes that a count value of the corresponding storage row is a count value satisfying a first numerical condition in all count values recorded in the primary recording unit set, and in response to a plurality of count values satisfying the first numerical condition, the count value of the corresponding storage row is a count value that satisfies a first time condition in the plurality of count values satisfying the first numerical condition.

14. The electronic device according to claim 10, wherein for writing the original row information in the first recording unit to the corresponding auxiliary recording unit in the auxiliary recording unit set, the one or more processors are configured to perform:
writing the original row information in the first primary recording unit to a second auxiliary recording unit satisfying a second access condition, wherein a corresponding auxiliary recording unit satisfying the second access condition characterizes that the row information, to be recorded, of the storage row is allowed to be written to the corresponding auxiliary recording unit.

15. The electronic device according to claim 14, wherein:
currently-accessed information stored in each primary recording unit includes a current count value of a number of accessed times of a corresponding storage row; and
the second access condition includes that a count value of the corresponding storage row is a count value satisfying a second numerical condition in all count values recorded in the primary recording unit set, and in response to a plurality of count values satisfying the second numerical condition, the count value of the corresponding storage row is a count value that satisfies a second time condition in the plurality of count values satisfying the second numerical condition.

16. The electronic device according to claim 10, wherein the one or more processors are further configured to perform:
in response to that currently-accessed information of a second row in the primary recording unit set satisfies a target condition, performing a target refresh processing on an adjacent row of the second row.

17. The electronic device according to claim 16, wherein for performing the target refresh processing on the adjacent row of the second row in response to that the currently-accessed information of the second row in the primary recording unit set satisfies the target condition, the one or more processors are configured to perform:
in response to that a current count value corresponding to a number of accessed times of the second row in the primary recording unit set reaches a threshold, generating a refresh instruction including a row address of the second row and target operation information, wherein the target operation information is configured to indicate a refresh operation corresponding to the target refresh processing;
based on the row address of the second row and a preset number of adjacent rows, determining a target adjacent row, corresponding to the second row, for the refresh operation to be performed; and
performing the refresh operation indicated by the target operation information on the target adjacent row.

18. The electronic device according to claim 16, wherein after performing the target refresh processing on the adjacent row of the second row, the one or more processors are further configured to perform:
resetting accessed information in row information, corresponding to the second row, to zero, thereby updating the accessed information in the row information corresponding to the second row from zero.

19. A non-transitory computer-readable storage medium containing a computer program that, when being executed, causes one or more processors to perform:
in response to that an access operation of a first row in a storage space of a storage component is detected, obtaining a row address of the first row; and
in response to that the row address of the first row is not recorded and no idle primary recording unit exists in a primary recording unit set, replacing row information in a first recording unit with row information corresponding to the first row, and writing original row information in the first recording unit to a corresponding auxiliary recording unit in an auxiliary recording unit set, wherein:
original row information recorded in a first primary recording unit satisfies a first access condition; row information in a corresponding primary recording unit satisfying the first access condition characterizes that the row information in the corresponding primary recording unit is allowed to be replaced; each recording unit in the primary recording unit set and the auxiliary recording unit set is configured to record row information of a corresponding storage row in the storage space of the storage component; the row information of the corresponding storage row includes a row address and currently-accessed information of a storage row indicated by the row address; the currently-accessed information is configured to determine whether a refresh operation is needed to be performed on an adjacent row of the corresponding storage row.

20. The storage medium according to claim 19, wherein the one or more processors are further configured to perform:
in response to that the row address of the first row is not recorded, and an idle primary recording unit exists in the primary recording unit set, writing the row information corresponding to the first row into the idle primary recording unit.
